(19) United States
(12) Patent Application Publication
(10) Pub. No.: US 2024/0290692 A1
(43) Pub. Date: Aug. 29, 2024

(54) IINTEGRATED CIRCUIT INCLUDING BACKSIDE WIRING AND METHOD OF MANUFACTURING THE INTEGRATED CIRCUIT

(71) Applicant: Samsung Electronics Co., Ltd., Suwon-si (KR)

(72) Inventors: Minjae Jeong, Suwon-si (KR); Jungho Do, Suwon-si (KR); Jisu Yu, Suwon-si (KR)

(21) Appl. No.: 18/404,529

(22) Filed: Jan. 4, 2024

(30) Foreign Application Priority Data
Feb. 27, 2023 (KR) 10-2023-0026114
Jun. 12, 2023 (KR) 10-2023-0075061

(51) Int. Cl. H01L 23/48; H01L 27/092; H01L 29/06; H01L 29/423; H01L 29/66; H01L 29/775; H01L 29/78; H01L 29/786

(52) U.S. Cl. CPC H01L 23/481; H01L 27/0924; H01L 29/0673; H01L 29/42392; H01L 29/66545; H01L 29/775; H01L 29/7851; H01L 29/78696

(57) ABSTRACT

An integrated circuit includes standard cells on a front surface of a substrate, a front wiring layer extending in a first direction on the front surface of the substrate, and a backside wiring layer disposed on a rear surface of the substrate. A first standard cell of the standard cells includes a first gate line and a second gate line arranged apart from each other in the first direction to each extend in a second direction and power tap cells between the first and second gate lines, the power tap cells include a first power tap cell and a second power tap cell apart from the first power tap cell by a first interval in the first direction, and each of the first and second power tap cells is configured to electrically connect the backside wiring layer with the front wiring layer.

### CROSS-REFERENCE TO RELATED APPLICATION

This application is based on and claims priority under 35 U.S.C. § 119 to Korean Patent Application Nos. 10-2023-0026114, filed on Feb. 27, 2023, and 10-2023-0075061, filed on Jun. 12, 2023, in the Korean Intellectual Property Office, the disclosure of which are incorporated by reference herein in their entirety.

### BACKGROUND

The inventive concept relates to an integrated circuit, and more particularly, to an integrated circuit including a backside wiring and a method of manufacturing the integrated circuit.

As high integration becomes more important and a semiconductor process advances, the widths, intervals, and/or heights of wirings included in an integrated circuit may decrease and the adverse effect of a parasitic element of a wiring may increase. Also, because a power supply voltage of integrated circuits may decrease for reduced power consumption and a high operation speed, the adverse effect of a parasitic element of a wiring on an integrated circuit may be even stronger. Therefore, demand has increased for a method of designing an integrated circuit for effectively routing wirings and vias.

### SUMMARY

The inventive concept provides an integrated circuit and a method of manufacturing the same, in which the complexity of routing may be reduced by using a front wiring layer and a backside wiring layer and a power tap cell may be disposed in a standard cell, and thus, area efficiency may be enhanced.

According to an aspect of the inventive concept, an integrated circuit includes a plurality of standard cells on a front surface of a substrate; a front wiring layer extending in a first direction on the front surface of the substrate; and a backside wiring layer on a rear surface of the substrate, wherein a first standard cell of the plurality of standard cells includes a first gate line and a second gate line arranged apart from each other in the first direction to each extend in a second direction perpendicular to the first direction; and a plurality of power tap cells between the first gate line and the second gate line, the plurality of power tap cells comprise a first power tap cell and a second power tap cell apart from the first power tap cell by a first interval in the first direction, and each of the first power tap cell and the second power tap cell is configured to electrically connect the backside wiring layer with the front wiring layer.

According to another aspect of the inventive concept, an integrated circuit includes a plurality of standard cells on a substrate; a front wiring layer extending in a first direction on a front surface of the substrate; and a backside wiring layer on a rear surface of the substrate, wherein a first standard cell of the plurality of standard cells includes a first gate line and a second gate line arranged apart from each other in the first direction to each extend in a second direction perpendicular to the first direction; and a power tap cell between the first gate line and the second gate line, the power tap cell including at least one via electrically connecting the backside wiring layer with the front wiring layer.

According to another aspect of the inventive concept, an integrated circuit includes a plurality of standard cells on a front surface of a substrate; a front wiring layer including a plurality of front wiring patterns arranged apart from one another in a second direction perpendicular to a first direction to each extend in the first direction on the front surface of the substrate; a backside wiring layer on a rear surface of the substrate; and a plurality of first inline power tap cells arranged in one row in the second direction to electrically connect the backside wiring layer with the front wiring layer, wherein a first standard cell of the plurality of standard cells includes a first gate line and a second gate line arranged apart from each other in the first direction to each extend in the second direction; and a first power tap cell between the first gate line and the second gate line to electrically connect the backside wiring layer with the front wiring layer, and the first power tap cell is aligned with the plurality of first inline power tap cells.

According to another aspect of the inventive concept, an integrated circuit includes a standard cell, the standard cell including a front wiring layer extending in a first direction on a front surface of a substrate; a backside wiring layer on a rear surface of the substrate; a first gate line, a second gate line, and a dummy gate line arranged apart from each other in the first direction to each extend in a second direction perpendicular to the first direction, wherein the dummy gate line is between the first gate line and the second gate line; and a power tap cell overlapping the dummy gate line, wherein the power tap cell is configured to electrically connect the backside wiring layer with the front wiring layer.

According to another aspect of the inventive concept, a method of manufacturing an integrated circuit includes, in a design of the integrated circuit, placing a plurality of first power tap cells in a line extending in a first direction; in the design of the integrated circuit, placing a standard cell including a second power tap cell; and manufacturing the integrated circuit based on the design of the integrated circuit.

### BRIEF DESCRIPTION OF THE DRAWINGS

Embodiments will be more clearly understood from the following detailed description taken in conjunction with the accompanying drawings in which:

FIG. 1 illustrates a layout of an integrated circuit according to an embodiment;

FIG. 2 is a perspective view schematically illustrating a partial region of the integrated circuit of FIG. 1, according to an embodiment;

FIG. 3A is an example of a cross-sectional view taken along line X1-X1′ of FIG. 1 according to an embodiment, FIG. 3B is an example of a cross-sectional view taken along line X1-X1′ of FIG. 1 according to an embodiment, and FIG. 3C is an example of a cross-sectional view taken along line X1-X1′ of FIG. 1 according to an embodiment;

FIG. 4 is a cross-sectional view taken along line X2-X2′ of FIG. 1 according to an embodiment;

FIGS. 5A to 5C respectively illustrate layouts of standard cells including a power tap cell, according to some embodiments;

FIG. 6A illustrates a layout of a standard cell according to an embodiment, and FIGS. 6B and 6C respectively illustrate layouts of standard cells according to comparative examples;

FIGS. 7A to 7D respectively illustrate layouts of standard cells according to some embodiments;

FIGS. 8A to 8C respectively illustrate layouts of standard cells each including a plurality of power tap cells, according to some embodiments;

FIG. 9 illustrates a layout of a standard cell according to an embodiment;

FIGS. 10 to 12 respectively illustrate layouts of integrated circuits according to some embodiments;

FIGS. 13A to 13D respectively illustrate devices according to some embodiments;

FIG. 14 is a flowchart illustrating a method of manufacturing an integrated circuit, according to an embodiment;

FIG. 15 is a block diagram illustrating a system on chip according to an embodiment; and

FIG. 16 is a block diagram illustrating a computing system including a memory storing a program, according to an embodiment.

### DETAILED DESCRIPTION OF THE EMBODIMENTS

Hereinafter, embodiments will be described in detail with reference to the accompanying drawings. Like reference numerals refer to like elements in the drawings, and their repeated descriptions are omitted.

As used herein, the term “standard cell” may refer to a unit circuit configured to perform a single operation such as a logic operation or a memory operation. In the case of a logic operation, examples of standard cells include a NAND gate, a NOR gate, an inverter, and a latch. A standard cell may be a memory cell(s) (e.g., a DRAM cell and a NAND string) to store a bit or several bits of data.

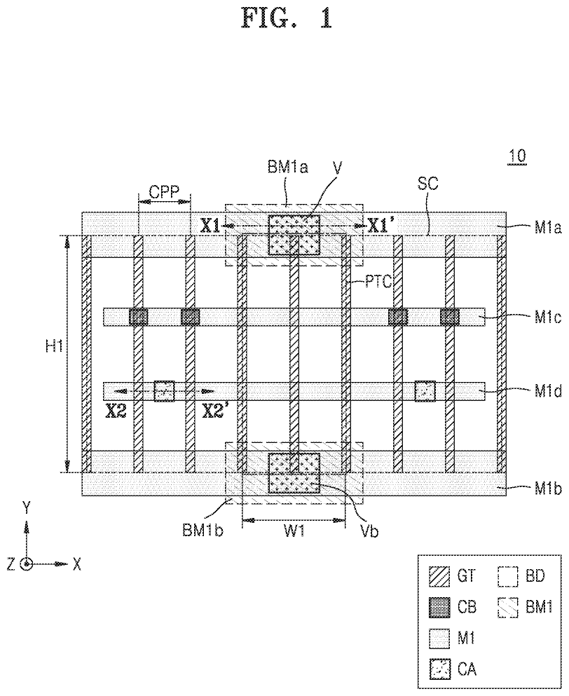

FIG. 1 illustrates a layout of an integrated circuit 10 according to an embodiment.

Referring to FIG. 1, the integrated circuit 10 may include a plurality of standard cells including a standard cell SC. According to an embodiment, the integrated circuit 10 may be referred to as an integrated circuit device or a semiconductor device. The standard cell SC may be a unit of a layout included in an integrated circuit, and according to embodiments, may be referred to as a cell. The standard cell SC may include a transistor and may be designed to perform a predefined function. In FIG. 1, the standard cell SC is illustrated as a single height cell, but the inventive concept is not limited thereto and the standard cell SC may be implemented as a multi height cell.

The standard cell SC may be defined by a cell boundary BD, may extend in a first direction X, and may have a first height H1 (e.g., a length) in a second direction Y. In this case, the first direction X may be referred to as a first horizontal direction, the second direction Y may be referred to as a second horizontal direction, and the first direction X may be perpendicular to the second direction Y. A plane consisting of the first direction X and the second direction Y may be referred to as a horizontal plane.

The standard cell SC may include gate lines GT, first contacts CA, and second contacts CB. Also, the standard cell SC may be designed to further include other elements. The gate lines GT may be apart from one another in the first direction X and may each extend in the second direction Y. First contacts CA may be respectively disposed in source/drain regions, and second contacts CB may be respectively disposed on the gate lines GT.

Also, the integrated circuit 10 may further include wiring layers including a front wiring layer M1 and a backside wiring layer BM1, so as to supply power and/or a signal to the standard cell SC. The front wiring layer M1 may include first to fourth front wiring patterns M1a to M1d which are disposed on a front surface of a substrate. The backside wiring layer BM1 may include first and second backside wiring patterns BM1a and BM1b which are disposed on a rear surface of the substrate.

According to an embodiment, the standard cell SC may further include a power tap cell PTC. In other words, the power tap cell PTC may be disposed in the standard cell SC. The power tap cell PTC may electrically connect the backside wiring layer BM1 with the front wiring layer M1 and may transfer a positive supply voltage or a negative supply voltage from the backside wiring layer BM1 to the front wiring layer M1. According to an embodiment, the power tap cell PTC may be referred to as a power pickup cell, a pickup cell, or a tap cell.

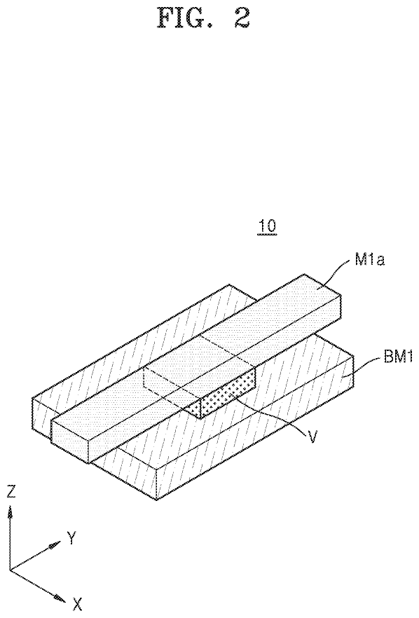

FIG. 2 is a perspective view schematically illustrating a partial region of the integrated circuit 10 of FIG. 1, according to an embodiment.

Referring to FIGS. 1 and 2, the power tap cell PTC may include a via pattern or a via V, which extends in a vertical direction Z. The via V may extend in the vertical direction Z between the backside wiring layer BM1 and the front wiring layer M1 and may electrically connect the backside wiring layer BM1 with the front wiring layer M1. The power tap cell PTC may have a first width W1 in the first direction X, and the first width W1 may be less than a width of the standard cell SC in the first direction X. For example, the first width W1 may correspond to a contacted poly pitch (2CPP), but the inventive concept is not limited thereto. Here, a CPP may correspond to a pitch of the gate lines GT. The power tap cell PTC may have a first height (e.g., a length in the second direction) H1 and a height of the standard cell SC in the second direction Y may be equal to the first height H1, but the inventive concept is not limited thereto.

As described above, the integrated circuit 10 may include a plurality of standard cells all or some of which may include features of the standard cell SC. Such standard cell scheme may be formed by a method which previously prepares standard cells and combines the standard cells to design a dedicated large-scale integrated circuit customized for the spec of a customer or a user. A standard cell may be previously designed and verified and may be registered in a standard cell library, and the integrated circuit 10 may be designed by performing a logic design where standard cells are combined, placed, and routed by using a computer aided design (CAD). In designing the integrated circuit 10, lengths and routing complexity of wirings and/or vias may decrease, and thus, the performance of the integrated circuit 10 may be more enhanced.

According to an embodiment, the integrated circuit 10 may implement a power distribution network (PDN) by using the front wiring layer M1 and the backside wiring layer BM1. In some examples, M1 may be the first metal layer on the front side of the integrated circuit 10 and BM1 may be the first metal layer on the backside of the integrated circuit 10 Therefore, some of signals and/or power each applied to the source/drain regions and/or the gate lines GT may be transferred through the front wiring layer M1, and the other may be transferred through the backside wiring layer BM1. Accordingly, according to an embodiment, the complexity of routing may be considerably reduced compared to a structure where wirings are disposed only on a front surface of a substrate, and a length of each wiring or each via may also be reduced, thereby enhancing the performance of the integrated circuit 10.

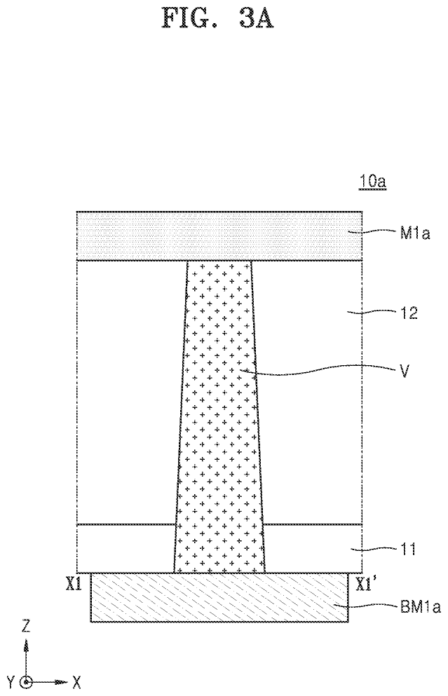

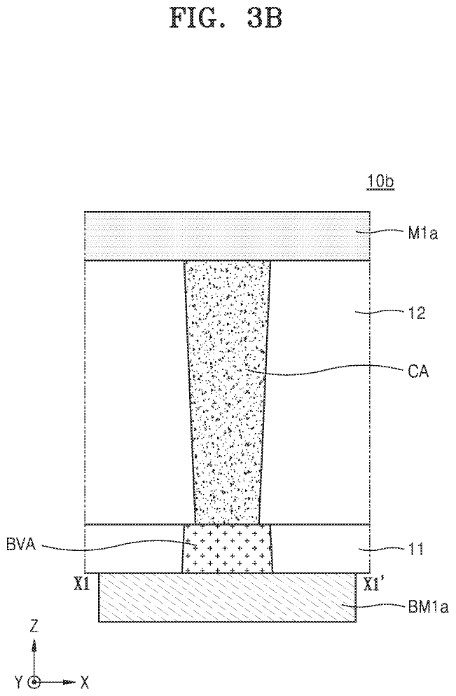

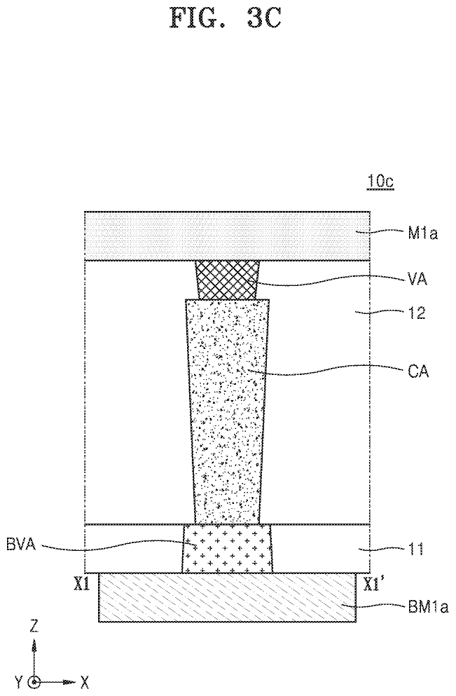

FIG. 3A is an example of a cross-sectional view taken along line X1-X1′ of FIG. 1 according to an embodiment.

Referring to FIGS. 1 and 3A, a first layer 11 may include a substrate such as a semiconductor substrate including a crystalline semiconductor material. For example, the semiconductor substrate may be or include one of a silicon-on-insulator (SOI), silicon-on-sapphire, germanium, silicon-germanium, and gallium-arsenide. However, the inventive concept is not limited thereto, and in an embodiment, the first layer 11 may include an insulation layer. For example, in performing a manufacturing process of an integrated circuit 10a, gate lines, source/drain regions, contacts, vias, and/or a wiring layer may be formed on a front surface of the substrate, and thus, a device wafer may be formed. Subsequently, the device wafer may be temporarily bonded to a carrier wafer, and a back-grinding process on the device wafer may be performed. At least a portion of the substrate (e.g., the backside of the substrate opposite to its front surface) may be removed by the back-grinding process, and an insulation layer may be formed on the backside of the substrate at locations where portions of the substrate have been removed. As described above, a wafer on which a back-grinding process has been performed so that a height of the substrate is less than or equal to a reference height may be referred to as a bulk-less wafer or a bulk-less substrate.

In FIG. 3A, the first layer 11 or an upper region of the first layer 11 may correspond to a device isolation layer such as shallow trench isolation (STI). An interlayer insulation layer 12 may be disposed on and contact the first layer 11 and may be formed of or include an insulating material. For example, the insulating material may include one of oxide, nitride, and oxynitride.

A first backside wiring pattern BM1a may extend in the first direction X at a rear surface of the first layer 11. A first front wiring pattern M1a may extend in the first direction X on the interlayer insulation layer 12. However, the inventive concept is not limited thereto, and an extension direction of the first backside wiring pattern BM1a and the first front wiring pattern M1a may be variously changed according to embodiments. A lower surface of the via V may contact the first backside wiring pattern BM1a, and an upper surface of the via V may contact the first front wiring pattern M1a.

FIG. 3B is an example of a cross-sectional view taken along line X1-X1′ of FIG. 1 according to an embodiment.

Referring to FIGS. 1 and 3B, an integrated circuit 10b may correspond to a modification example of the integrated circuit 10a of FIG. 3A, and descriptions given above with reference to FIG. 3A may be applied to an embodiment. For example, the power tap cell PTC may be implemented to include a backside via BVA and a first contact CA. The backside via BVA may be disposed on the first backside wiring pattern BM1a and may pass through the first layer 11 and extend in the vertical direction Z. The first contact CA may be disposed on the backside via BVA and may pass through the interlayer insulation layer 12 and extend in the vertical direction Z. Therefore, the first backside wiring pattern BM1a may be electrically connected with the first front wiring pattern M1a through the backside via BVA and the first contact CA.

FIG. 3C is an example of a cross-sectional view taken along line X1-X1′ of FIG. 1 according to an embodiment.

Referring to FIGS. 1 and 3C, an integrated circuit 10c may correspond to a modification example of the integrated circuit 10a of FIG. 3A, and descriptions given above with reference to FIG. 3A may be applied to an embodiment. For example, the power tap cell PTC may be implemented to include a backside via BVA, a first contact CA, and a first via VA. The backside via BVA may be disposed on the first backside wiring pattern BM1a and may pass through the first layer 11 and extend in the vertical direction Z. The first contact CA may be disposed on the backside via BVA and may pass through the interlayer insulation layer 12 and extend in the vertical direction Z. The first via VA may be disposed on the first contact CA and may pass through the interlayer insulation layer 12 and extend in the vertical direction Z. Therefore, the first backside wiring pattern BM1a may be electrically connected with the first front wiring pattern M1a through the backside via BVA, the first contact CA, and the first via VA.

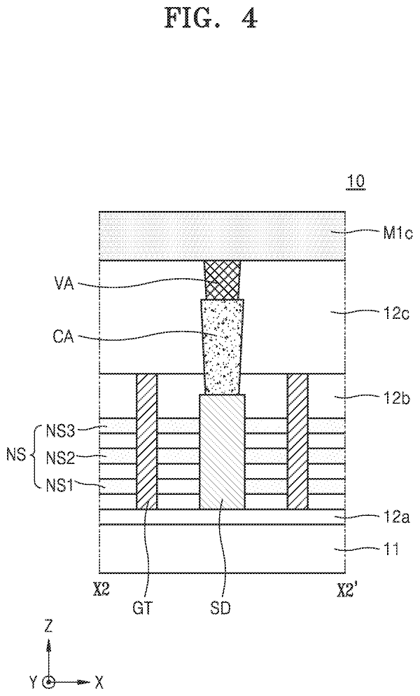

FIG. 4 is a cross-sectional view taken along line X2-X2′ of FIG. 1 according to an embodiment.

Referring to FIGS. 1 and 4, the interlayer insulation layer 12 may include interlayer insulation layers 12a to 12c. A nanosheet stack NS extending in the first direction X may be disposed on the interlayer insulation layer 12a. The nanosheet stack NS may include a plurality of nanosheets (for example, first to third nanosheets NS1 to NS3) which overlap in the vertical direction Z. For example, the nanosheet stack NS disposed on an N-well may be doped with N-type impurities and may form a P-type transistor. On the other hand, the nanosheet stack NS disposed on a P-type substrate may be doped with P-type impurities and may form an N-type transistor. In an embodiment, the nanosheets NS may be formed of or include silicon (Si), germanium (Ge), or SiGe. In an embodiment, the nanosheets NS may include InGaAs, InAs, GaSb, InSb, or a combination thereof.

Each of the gate lines GT may cover portions of the nanosheet NS and may surround portions of each of the first to third nanosheets NS1 to NS3. Therefore, the first to third nanosheets NS1 to NS3 may have a gate-all-around (GAA) structure. A gate insulation layer may be disposed between each of the gate lines GT and the first to third nanosheets NS1 to NS3. The gate lines GT may be formed of or include, for example, a metal material such as tungsten (W) or tantalum (Ta), nitride thereof, silicide thereof, or doped polysilicon, and for example, may be formed by a deposition process.

A source/drain region SD may be disposed between the gate lines GT. For example, the source/drain region SD may include an epitaxial region of a semiconductor material. The first contact CA may be disposed on the source/drain region SD, the first via VA may be disposed on the first contact CA, and a third front wiring pattern M1c may be disposed on the first via VA. The first contact CA and the first via VA may be formed of or include, for example, a material having electrical conductivity like tungsten.

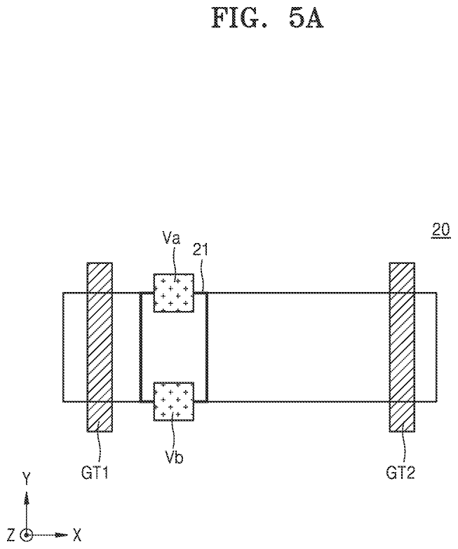

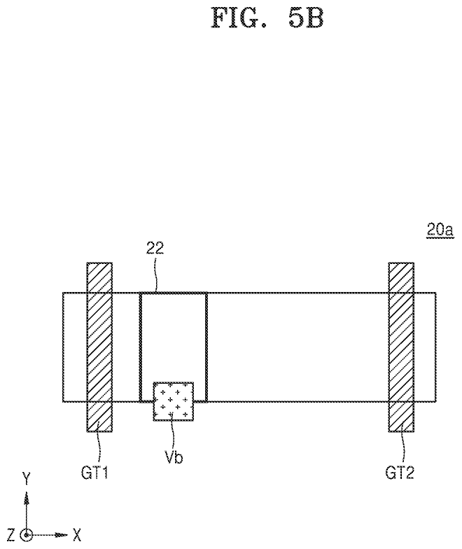

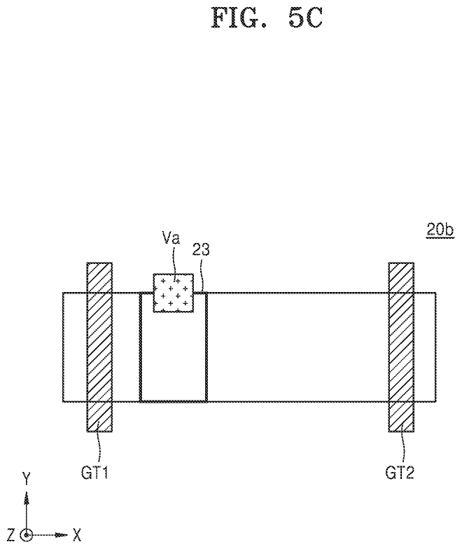

FIG. 5A illustrates a layout of a standard cell 20 including a power tap cell, according to an embodiment.

Referring to FIG. 5A, the standard cell 20 may include first and second gate lines GT1 and GT2 and a power tap cell 21. The first and second gate lines GT1 and GT2 may be apart from each other in a first direction X and may each extend in a second direction Y (e.g., the extending direction referring to the longer dimension of the line providing a path for the transmission of current). The power tap cell 21 may be disposed between the first and second gate lines GT1 and GT2. The power tap cell 21 may include vias Va and Vb. The vias Va and Vb may protrude in the second direction Y such that a boundary of the standard cell 20 protrudes in the second direction Y at the positions of the vias Va and Vb as shown, e.g., in FIG. 5A. For example, the via Va may receive a source voltage or power supply voltage VDD and may be connected with a PMOS transistor. For example, the via Vb may receive a ground voltage VSS and may be connected with an NMOS transistor. As described above, the power tap cell 21 may include the vias Va and Vb and may thus provide a supply voltage to both the PMOS transistor and the NMOS transistor.

FIG. 5B illustrates a layout of a standard cell 20a including a power tap cell, according to an embodiment.

Referring to FIG. 5B, the standard cell 20a may include first and second gate lines GT1 and GT2 and a power tap cell 22. The first and second gate lines GT1 and GT2 may be apart from each other in a first direction X and may each extend in a second direction Y. The power tap cell 22 may be disposed between the first and second gate lines GT1 and GT2. The power tap cell 22 may include a via Vb. The via Vb may overlap a cell boundary of the standard cell 20a. For example, the via Vb may receive a ground voltage VSS and may be connected with an NMOS transistor. As described above, the power tap cell 22 may include the via Vb and may thus provide a supply voltage to the NMOS transistor.

FIG. 5C illustrates a layout of a standard cell 20b including a power tap cell, according to an embodiment.

Referring to FIG. 5C, the standard cell 20b may include first and second gate lines GT1 and GT2 and a power tap cell 23. The first and second gate lines GT1 and GT2 may be apart from each other in a first direction X and may each extend in a second direction Y. The power tap cell 23 may be disposed between the first and second gate lines GT1 and GT2. The power tap cell 23 may include a via Va. The via Va may overlap a cell boundary of the standard cell 20b. For example, the via Va may receive a source voltage or power supply voltage VDD and may be connected with a PMOS transistor. As described above, the power tap cell 23 may include the via Va and may thus provide a supply voltage to the PMOS transistor.

As described above with reference to FIGS. 5A to 5C, a structure of a power tap cell included in a standard cell may be variously changed according to an embodiment. Based on the placement of transistors of the standard cell, the standard cell may include a power tap cell which receives a source voltage or power supply voltage VDD, a power tap cell which receives a ground voltage VSS, and/or a power tap cell which receives the power supply voltage VDD and the ground voltage VSS.

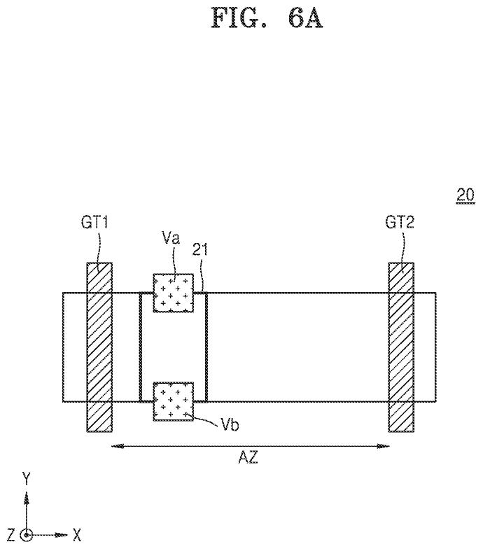

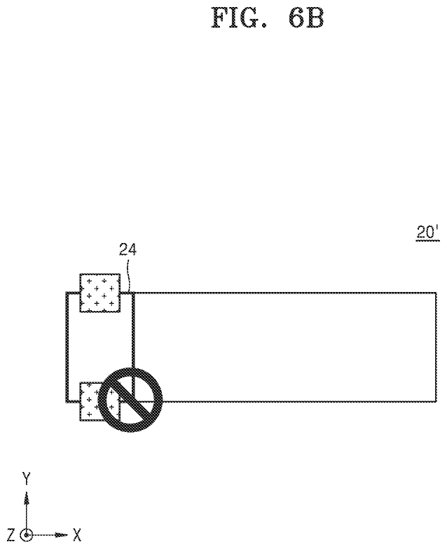

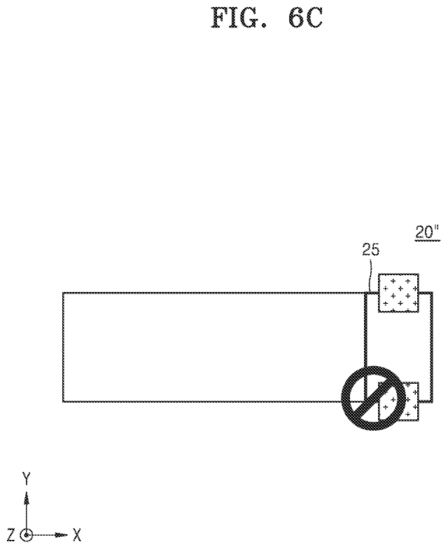

FIG. 6A illustrates a layout of a standard cell 20 according to an embodiment, and FIGS. 6B and 6C respectively illustrate layouts of standard cells according to comparative examples.

Referring to FIGS. 6A to 6C, the standard cell 20 may correspond to the standard cell 20 of FIG. 5A. The power tap cell 21 may be disposed in an available zone AZ. In this case, the available zone AZ may correspond to a region between a first gate line GT1 and a second gate line GT2. For example, as in a standard cell 20′ of a comparative example shown in FIG. 6B, a power tap cell 24 may not be able to be disposed adjacent to or overlap a left cell boundary, outside the available zone AZ. Also, for example, as in a standard cell 20″ shown in FIG. 6C, a power tap cell 25 may not be able to be disposed to be adjacent to or overlap a right cell boundary, outside the available zone AZ. In an operation of placing a standard cell, the standard cells 20′ and 20″ where the power tap cells 24 and 25 are respectively disposed in a cell boundary may be replaced with the standard cell 20.

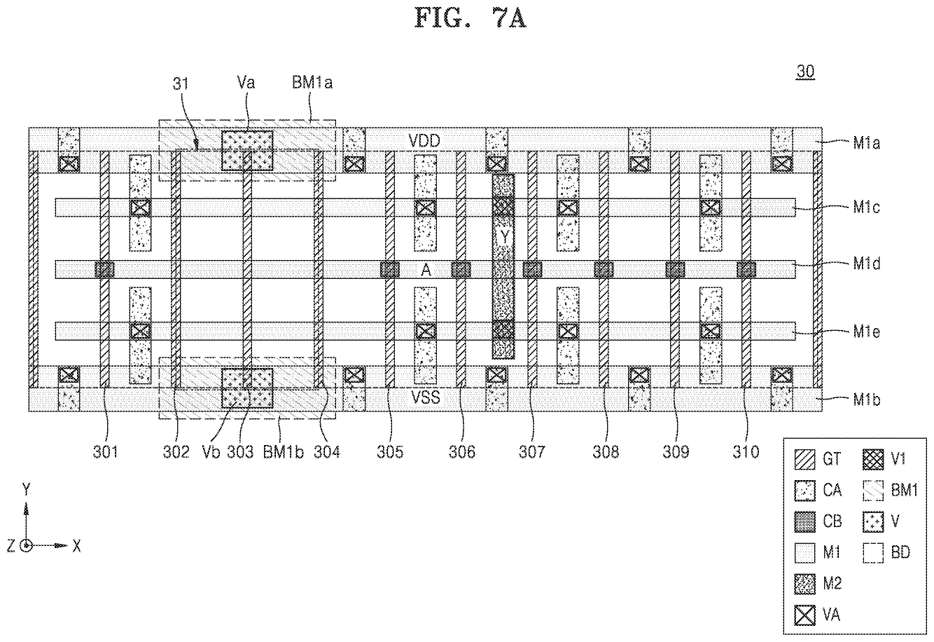

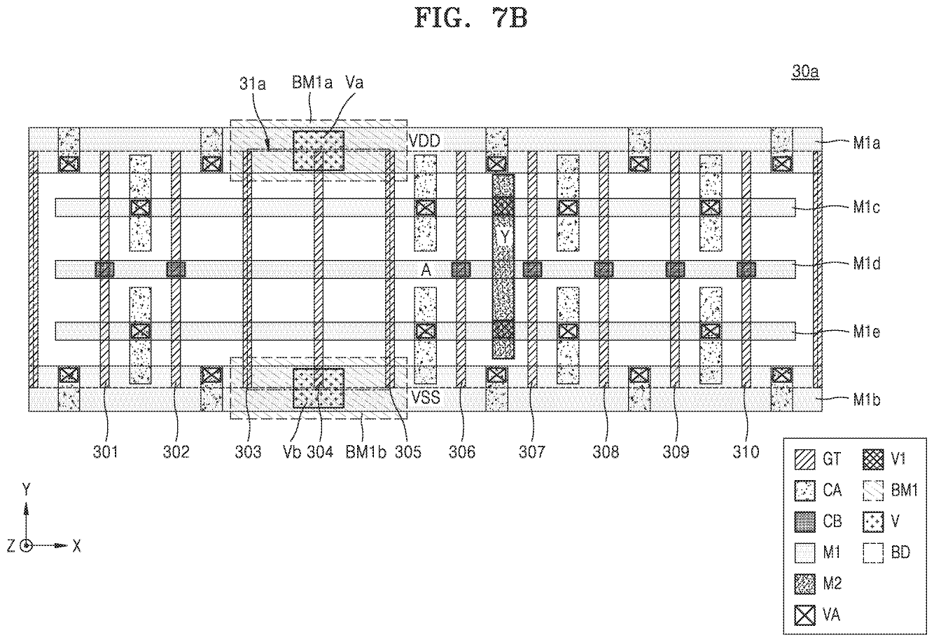

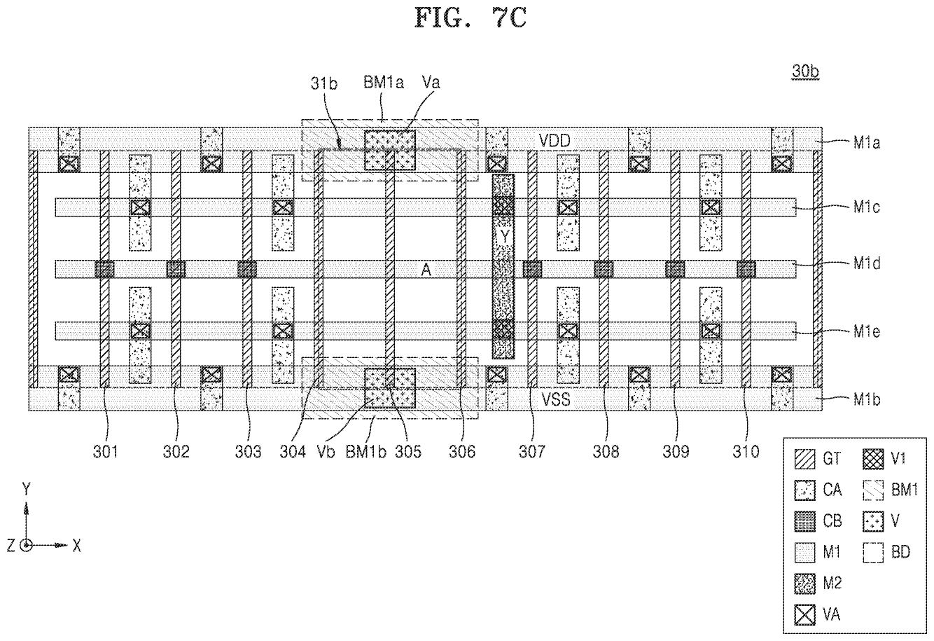

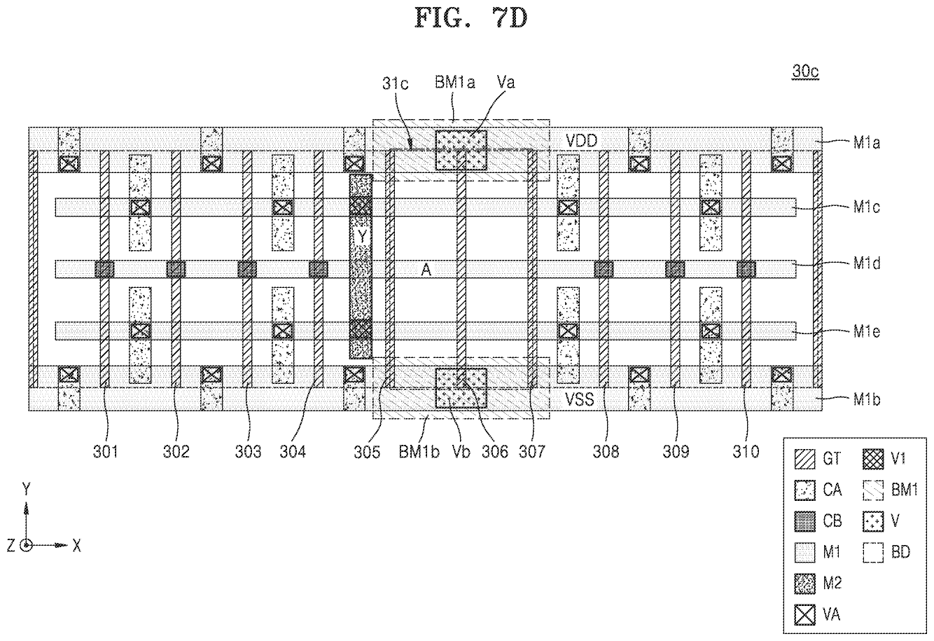

FIG. 7A illustrates a layout of an integrated circuit 30 according to an embodiment.

Referring to FIG. 7A, the integrated circuit 30 may include gate lines GT, first contacts CA, second contacts CB, a first front wiring layer M1, a second front wiring layer M2, a first via VA, a second via V1, a backside wiring layer BM1, and a via V. The gate lines GT may include gate lines 301 to 310 which are apart from one another in a first direction X and each extend in a second direction Y. The first front wiring layer M1 may include first to fifth front wiring patterns M1a to M1e which each extend in the first direction X, and the backside wiring layer BM1 may include first and second backside wiring patterns BM1a and BM1b.

The first front wiring layer M1 may be disposed on a front surface of a substrate, and the backside wiring layer BM1 may be disposed on a rear surface of the substrate. For example, the substrate may be a P-type semiconductor substrate, and an N-well may be disposed in the P-type semiconductor substrate. PMOS transistors may be formed on the N-well, and NMOS transistors may be formed on the P-type semiconductor substrate. For example, the first front wiring pattern M1a may correspond to a first power rail which transfers a source voltage or power supply voltage VDD to the PMOS transistors on the N-well. For example, the second front wiring pattern M1b may correspond to a second power rail which transfers a ground voltage VSS to the NMOS transistors. The fourth front wiring pattern M1d may correspond to an input node and may be connected with the gate lines 301, 305, 306, 307, 308, 309, and 310 through the second contacts CB. The third and fifth front wiring patterns M1c and M1e may correspond to output nodes and may be connected with the second front wiring layer M2 through the second vias V1.

In an embodiment, the integrated circuit 30 may include a standard cell which is defined by a cell boundary BD, and the power tap cell 31 may be disposed in the standard cell. The power tap cell 31 may include vias Va and Vb, the via Va may electrically connect the first backside wiring pattern BM1a with the first front wiring pattern M1a, and the via Vb may electrically connect the second backside wiring pattern BM1b with the second front wiring pattern M1b. In this case, the gate lines 302, 303, and 304 overlapping the power tap cell 31 may be dummy gate lines.

As referred to herein, a dummy gate line is a conductive line formed at the same level and adjacent to normal gate lines (e.g., normal word lines). A dummy gate line is patterned from the same conductive layer(s) forming such normal word lines. For example, a dummy gate line may be simultaneously formed with normal gate lines with the same processes that deposit and pattern the conductive layer(s) forming normal word lines. Dummy gate lines in memory devices are not effective to cause transmission of data to external devices. For instance, a dummy gate line may not be electrically connected to gates of memory cells, or if a dummy gate line is electrically connected to gates of dummy memory cells, such dummy gate lines may not be activated or if activated, may not result in communication of any data in such dummy memory cells to a source external to the memory device.

In an embodiment, the gate line 301 may correspond to the first gate line GT1 of FIG. 6A, and the gate line 310 may correspond to the second gate line GT2 of FIG. 6A. In this case, a region between the gate lines 301 and 310 may correspond to an available zone. For example, the power tap cell 31 may be disposed between the gate lines 301 and 305 in the available zone.

FIG. 7B illustrates a layout of an integrated circuit 30a according to an embodiment.

Referring to FIG. 7B, the integrated circuit 30a may correspond to a modification example of the integrated circuit 30 of FIG. 7A. The integrated circuit 30a may include a power tap cell 31a disposed in a standard cell, and the power tap cell 31a may be disposed in an available zone between the gate lines 301 and 310. For example, the power tap cell 31a may be disposed to overlap the gate lines 303, 304, and 305, and in this case, the gate lines 303, 304, and 305 may be dummy gate lines. For example, the power tap cell 31a may be disposed between the gate lines 302 and 306.

FIG. 7C illustrates a layout of an integrated circuit 30b according to an embodiment.

Referring to FIG. 7C, the integrated circuit 30b may correspond to a modification example of the integrated circuit 30 of FIG. 7A. The integrated circuit 30b may include a power tap cell 31b disposed in a standard cell, and the power tap cell 31b may be disposed in an available zone between the gate lines 301 and 310. For example, the power tap cell 31b may be disposed to overlap the gate lines 304, 305, and 306, and in this case, the gate lines 304, 305, and 306 may be dummy gate lines. For example, the power tap cell 31b may be disposed between the gate lines 303 and 307.

FIG. 7D illustrates a layout of an integrated circuit 30c according to an embodiment.

Referring to FIG. 7D, the integrated circuit 30c may correspond to a modification example of the integrated circuit 30 of FIG. 7A. The integrated circuit 30c may include a power tap cell 31c disposed in a standard cell, and the power tap cell 31c may be disposed in an available zone between the gate lines 301 and 310. For example, the power tap cell 31c may be disposed to overlap the gate lines 305, 306, and 307, and in this case, the gate lines 305, 306, and 307 may be dummy gate lines. For example, the power tap cell 31c may be disposed between the gate lines 304 and 308.

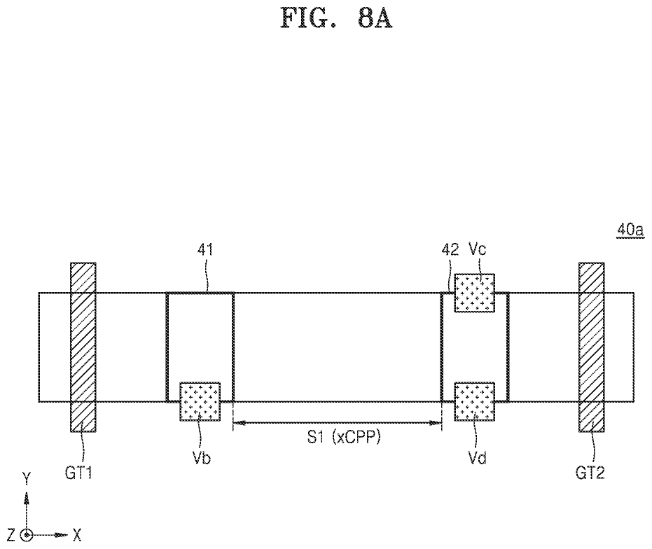

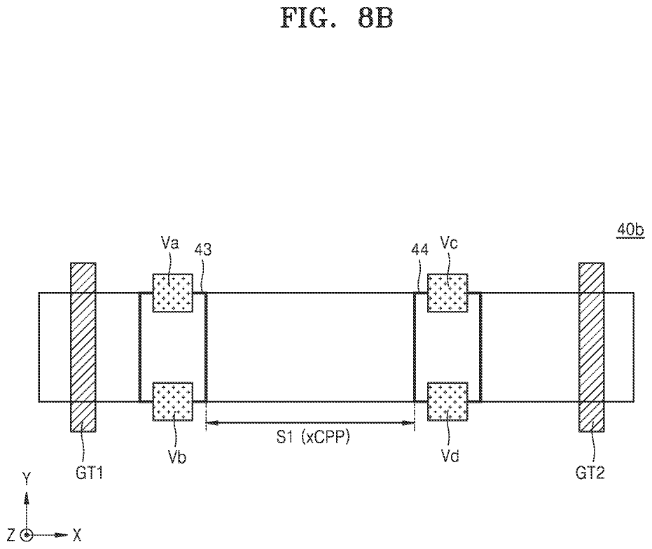

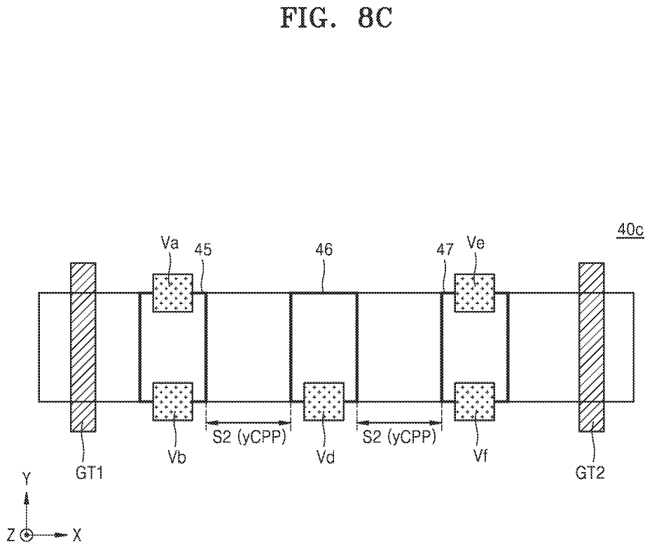

FIG. 8A illustrates a layout of a standard cell 40a including a plurality of power tap cells, according to an embodiment.

Referring to FIG. 8A, the standard cell 40a may include first and second gate lines GT1 and GT2 and power tap cells 41 and 42. The first and second gate lines GT1 and GT2 may be apart from each other in a first direction X and may each extend in a second direction Y. The first and second power tap cells 41 and 42 may be disposed between the first and second gate lines GT1 and GT2. In this case, a zone between the first and second gate lines GT1 and GT2 may be defined as an available zone. An interval between the first and second power tap cells 41 and 42 may be a first interval S1. Here, the first interval S1 may correspond to an xCPP, and x may be a positive integer.

In an embodiment, the first and second power tap cells 41 and 42 may have different structures. For example, the first power tap cell 41 may include a via Vb and the second power tap cell 42 may include vias Vc and Vd. The vias Vb, Vc, and Vd may overlap a cell boundary of the standard cell 40a. For example, the via Vc may receive a source voltage or power supply voltage VDD and may be connected with a PMOS transistor. For example, the vias Vb and Vd may receive a ground voltage VSS and may be connected with an NMOS transistor. As described above, because the first power tap cell 41 includes the via Vb, the first power tap cell 41 may provide a supply voltage to the NMOS transistor, and because the second power tap cell 42 includes the vias Vc and Vd, the second power tap cell 42 may provide the supply voltage to both the PMOS transistor and the NMOS transistor.

FIG. 8B illustrates a layout of a standard cell 40b including a plurality of power tap cells, according to an embodiment.

Referring to FIG. 8B, the standard cell 40b may include first and second gate lines GT1 and GT2 and first and second power tap cells 43 and 44. The first and second gate lines GT1 and GT2 may be apart from each other in a first direction X and may each extend in a second direction Y. The first and second power tap cells 43 and 44 may be disposed between the first and second gate lines GT1 and GT2. In this case, a zone between the first and second gate lines GT1 and GT2 may be defined as an available zone. An interval between the first and second power tap cells 43 and 44 may be a first interval S1. For example, the first interval S1 may correspond to the first interval S1 of FIG. 8A.

In an embodiment, the first and second power tap cells 43 and 44 may have the same structure. For example, the first power tap cell 43 may include vias Va and Vb and the second power tap cell 44 may include vias Vc and Vd. The vias Va, Vb, Vc, and Vd may overlap a cell boundary of the standard cell 40b. For example, the vias Va and Vc may receive a source voltage or power supply voltage VDD and may be connected with a PMOS transistor. For example, the vias Vb and Vd may receive a ground voltage VSS and may be connected with an NMOS transistor. As described above, because the first power tap cell 43 includes the vias Va and Vb, the first power tap cell 43 may provide a supply voltage to both the PMOS transistor and the NMOS transistor, and because the second power tap cell 44 includes the vias Vc and Vd, the second power tap cell 44 may provide the supply voltage to both the PMOS transistor and the NMOS transistor.

FIG. 8C illustrates a layout of a standard cell 40c including a plurality of power tap cells, according to an embodiment.

Referring to FIG. 8C, the standard cell 40c may include first and second gate lines GT1 and GT2 and first to third power tap cells 45 to 47. The first and second gate lines GT1 and GT2 may be apart from each other in a first direction X and may each extend in a second direction Y. The first to third power tap cells 45 to 47 may be disposed between the first and second gate lines GT1 and GT2. In this case, a zone between the first and second gate lines GT1 and GT2 may be defined as an available zone. An interval between the first to third power tap cells 45 to 47 may be a second interval S2. Here, the second interval S2 may correspond to a yCPP, and y may be a positive integer.

In an embodiment, the first to third power tap cells 45 to 47 may have different structures. For example, the first power tap cell 45 may include the vias Va and Vb, the second power tap cell 46 may include the via Vd, and the third power tap cell 47 may include the vias Ve and Vf. The vias Va, Vb, Vd, Ve, and Vf may overlap a cell boundary of the standard cell 40c. For example, the vias Va and Ve may receive a source voltage or power supply voltage VDD and may be connected with a PMOS transistor. For example, the vias Vb, Vd, and Vf may receive a ground voltage VSS and may be connected with an NMOS transistor. As described above, the first and third power tap cells 45 and 47 may provide a supply voltage to both the PMOS transistor and the NMOS transistor, and the second power tap cell 46 may provide the supply voltage to the NMOS transistor. However, the inventive concept is not limited thereto, and in some embodiments, the first to third power tap cells 45 to 47 may have the same structure.

FIG. 9 illustrates a layout of an integrated circuit 50 according to an embodiment.

Referring to FIG. 9, the integrated circuit 50 may include gate lines GT, first contacts CA, second contacts CB, a first front wiring layer M1, a second front wiring layer M2, a first via VA, a second via V1, a backside wiring layer BM1, and a via V. The gate lines GT may include gate lines 501 to 513 which are apart from one another in a first direction X and each extend in a second direction Y. The first front wiring layer M1 may include first to fifth front wiring patterns M1a to M1e which each extend in the first direction X, and the backside wiring layer BM1 may include first to fourth backside wiring patterns BM1a to BM1d.

The first front wiring layer M1 may be disposed on a front surface of a substrate, and the backside wiring layer BM1 may be disposed on a rear surface of the substrate. For example, the substrate may be a P-type semiconductor substrate, and an N-well may be disposed in the P-type semiconductor substrate. PMOS transistors may be formed on the N-well, and NMOS transistors may be formed on the P-type semiconductor substrate. For example, the first front wiring pattern M1a may correspond to a first power rail which transfers a source voltage or power supply voltage VDD to the PMOS transistors on the N-well. For example, the second front wiring pattern M1b may correspond to a second power rail which transfers a ground voltage VSS to the NMOS transistors. The fourth front wiring pattern M1d may correspond to an input node and may be connected with gate lines 501, 505, 506, 507, 511, 512, and 513 through the second contacts CB. The third and fifth front wiring patterns M1c and M1e may correspond to output nodes and may be connected with the second front wiring layer M2 through the second vias V1.

In an embodiment, the integrated circuit 50 may include a standard cell which is defined by a cell boundary BD, and the first and second power tap cells 51 and 52 may be disposed in the standard cell. The first power tap cell 51 may include vias Va and Vb. The via Va may electrically connect the first backside wiring pattern BM1a with the first front wiring pattern M1a, and the via Vb may electrically connect the second backside wiring pattern BM1b with the second front wiring pattern M1b. In this case, the gate lines 502, 503, and 504 overlapping the first power tap cell 51 may be dummy gate lines. The second power tap cell 52 may include vias Vc and Vd. The via Vc may electrically connect the third backside wiring pattern BM1c with the first front wiring pattern M1a, and the via Vd may electrically connect the fourth backside wiring pattern BM1d with the second front wiring pattern M1b. In this case, the gate lines 508, 509, and 510 overlapping the second power tap cell 52 may be dummy gate lines.

In an embodiment, the gate line 501 may correspond to the first gate line GT1 of FIG. 6A, and the gate line 513 may correspond to the second gate line GT2 of FIG. 6A. In this case, a region between the gate lines 501 and 513 may correspond to an available zone AZ. For example, the first and second power tap cells 51 and 52 may be disposed between the gate lines 501 and 513 in the available zone. For example, an interval between the first and second power tap cells 51 and 52 may correspond to a first interval S1, and the first interval S1 may correspond to an xCPP.

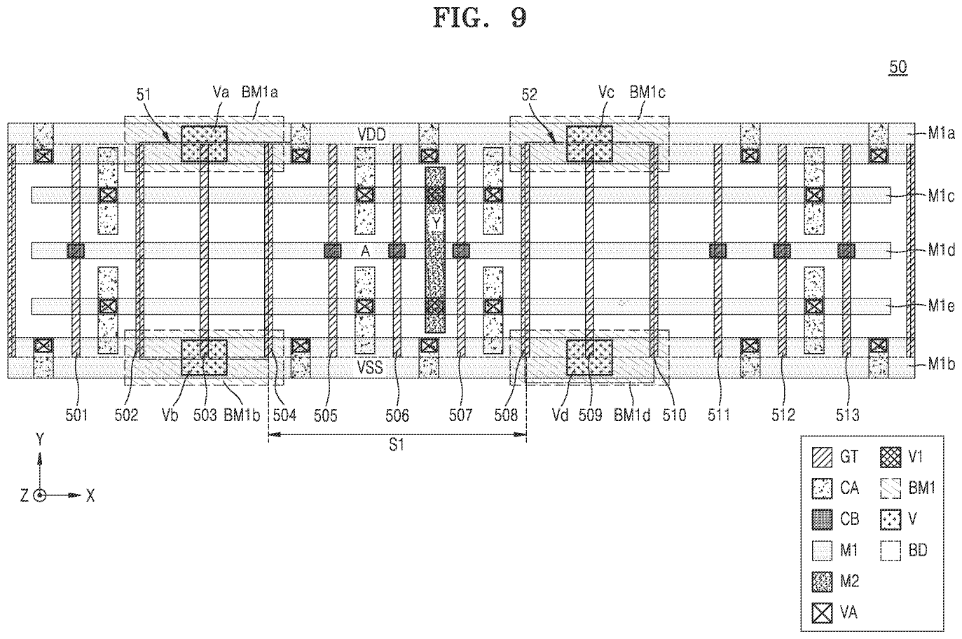

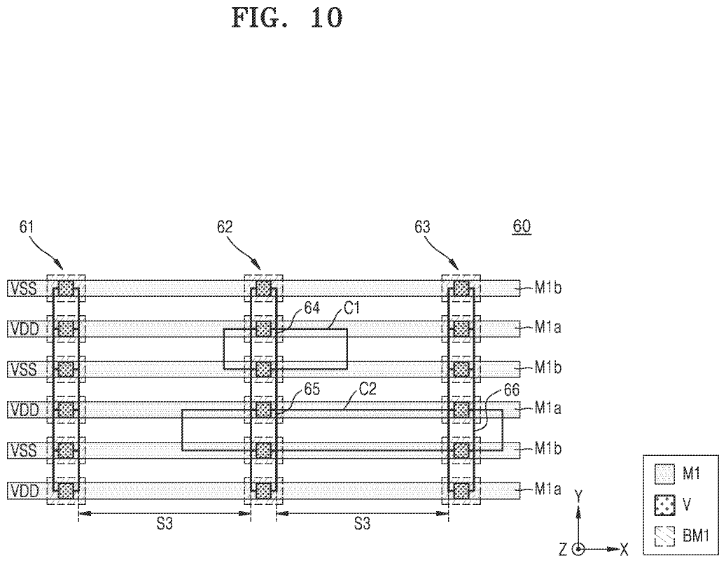

FIG. 10 illustrates a layout of an integrated circuit 60 according to an embodiment.

Referring to FIG. 10, the integrated circuit 60 may correspond to a block or a circuit block where a plurality of standard cells are disposed, so as to perform a specific function. The integrated circuit 60 may include a front wiring layer M1, a backside wiring layer BM1, and vias V connected between the front wiring layer M1 and the backside wiring layer BM1. According to an embodiment, the integrated circuit 60 may further include first and second standard cells C1 and C2, and the first and second standard cells C1 and C2 may be freely disposed in the block of the integrated circuit 60.

The front wiring layer M1 may include first and second power rails or first and second front wiring patterns M1a and M1b, which each extend in a first direction X and are alternately arranged. For example, the first front wiring pattern M1a may receive a source voltage or power supply voltage VDD and the second front wiring pattern M1b may receive a ground voltage VSS. The backside wiring layer BM1 may include a plurality of backside wiring patterns. The placement and/or extension direction of the backside wiring layer BM1 may be variously changed according to an embodiment.

The integrated circuit 60 may further include power tap cells 61 to 63 each including a via which electrically connects the front wiring layer M1 with the backside wiring layer BM1. The power tap cells 61 may be arranged in one row in a second direction Y and may thus be referred to as first inline power tap cells 61. The power tap cells 62 may be arranged in one row in the second direction Y and may thus be referred to as second inline power tap cells 62. The power tap cells 63 may be arranged in one row in the second direction Y and may thus be referred to as third inline power tap cells 63.

Generally, power tap cells may be first arranged in a line, and subsequently, standard cells may be placed between the power tap cells, thereby a block of an integrated circuit for performing a desired function may be designed. In the related art, standard cells or function cells may not be placed in a region where power tap cells are arranged in a line, namely, a region where inline power tap cells are disposed. As described above, a forbidden zone where standard cells are incapable of being placed may occur and the placement of a standard cell may be partially limited, and due to this, an area penalty of a block may occur (e.g., the designed block may be larger than necessary to accommodate the limitations imposed in placing the standard cell).

However, according to an embodiment, by using the first standard cell C1 including the power tap cell 64, standard cells may be placed without a limitation of a forbidden zone. In detail, the first standard cell C1 may be placed so that the power tap cell 64 is aligned with the second inline power tap cells 62. For example, the first standard cell C1 including the power tap cell 64 may be placed instead of a specific power tap cell among the second inline power tap cells 62. In other words, in an operation of placing standard cells, the specific power tap cell may be swapped or overwritten with the first standard cell C1, and thus, a block (i.e., the integrated circuit 60) may be designed. For example, after placing second power tap cells 62 for a block of an integrated circuit (e.g., in one or more lines of second power tap cells 62), the first standard cell C1 including the power tap cell 64 may be placed, and the power tap cell 64 of the first standard cell C1 may be swapped for one of the previously placed second power tap cells 62. The first standard cell C1 may be placed such that its power tap cell 64 is located at the location of the second power tap cell 62 that is replaced. In some examples, the standard cell library may include several versions of a standard cell providing the same function (e.g., several versions of a memory cell standard cell, several versions of an inverter standard cell, etc.) and that may have the same size (e.g., occupy the same area in the integrated circuit). These versions of the same function standard cell may have different locations of their power tap cells 64, and thus one of these versions may be selected to optimize placement of the standard cell (e.g., to avoid/reduce an area penalty) while allowing its power tap cell 64 to replace a previously placed second power tap cell 62. In some examples, the versions of the same function standard cell may be identical with respect to the layout of the standard cell on the frontside of the integrated circuit but vary in the location of their power tap cells 64 and related connections to the portion of the standard cell on the frontside of the integrated circuit. In some examples, separate standard cells may define second power tap cells 62 without defining other functions (e.g., without being part of a logic cell or memory cell standard cell). In some examples, separate standard cells defining second power tap cells 62 may not be used in all or part of the integrated circuit and the power tap cells 64 may be initially placed using standard cells SC including one or more power tap cells 64.

Also, in the related art, a region where standard cells are placed may be limited to a region between inline power tap cells (for example, a region between the first and second inline power tap cells 61 and 62 and a region between the second and third inline power tap cells 62 and 63), and thus, it may be difficult to place a standard cell having a width which is greater than the third interval S3. Accordingly, a problem may occur where it is difficult to enhance the performance of an integrated circuit by using various standard cells.

However, according to an embodiment, a plurality of power tap cells 65 and 66 may be placed in a standard cell having a width which is greater than the third interval S3, and thus, the performance of the integrated circuit 60 and the degree of freedom in placement of standard cells may be enhanced. In this case, a width of the second standard cell C2 may be greater than the third interval S3, but the second standard cell C2 may be placed so that the power tap cell 65 is aligned with the second inline power tap cells 62 and the power tap cell 66 is aligned with the third inline power tap cells 63. For example, the second standard cell C2 including the power tap cells 65 and 66 may be placed instead of a first specific power tap cell of the second inline power tap cells 62 and a second specific power tap cell of the third inline power tap cells 63. In other words, in an operation of placing standard cells, the first and second specific power tap cells may be swapped or overwritten with the second standard cell C2, and thus, a block (i.e., the integrated circuit 60) may be designed.

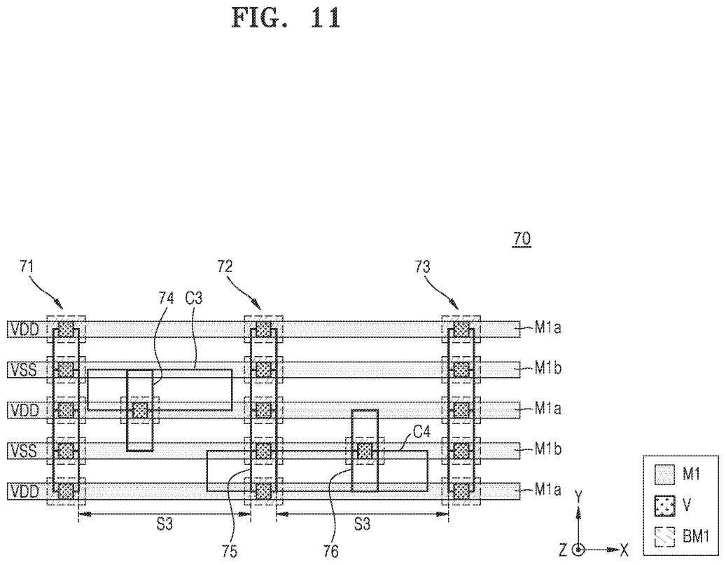

FIG. 11 illustrates a layout of an integrated circuit 70 according to an embodiment.

Referring to FIG. 11, the integrated circuit 70 may correspond to a block or a circuit block where a plurality of standard cells are disposed, so as to perform a specific function. The integrated circuit 70 may include a front wiring layer M1, a backside wiring layer BM1, and vias V connected between the front wiring layer M1 and the backside wiring layer BM1. According to an embodiment, the integrated circuit 70 may further include third and fourth standard cells C3 and C4, and the third and fourth standard cells C3 and C4 may be freely disposed in the block of the integrated circuit 70.

The front wiring layer M1 may include first and second power rails or first and second front wiring patterns M1a and M1b, which each extend in a first direction X and are alternately arranged. For example, the first front wiring pattern M1a may receive a source voltage or power supply voltage VDD and the second front wiring pattern M1b may receive a ground voltage VSS. The backside wiring layer BM1 may include a plurality of backside wiring patterns. The placement and/or extension direction of the backside wiring layer BM1 may be variously changed according to an embodiment.

The integrated circuit 70 may further include power tap cells 71 to 73 each including a via which electrically connects the front wiring layer M1 with the backside wiring layer BM1. The power tap cells 71 may be arranged in one row in the second direction Y and may thus also be referred to as first inline power tap cells 71. The power tap cells 72 may be arranged in one row in the second direction Y and may thus also be referred to as second inline power tap cells 72. The power tap cells 73 may be arranged in one row in the second direction Y and may thus also be referred to as third inline power tap cells 73.

According to an embodiment, the third and fourth standard cells C3 and C4 may be placed. The third standard cell C3 may include a power tap cell 74, and the power tap cell 74 may be placed as an island type between the first and second inline power tap cells 71 and 72. Therefore, a PMOS transistor included in the third standard cell C3 may receive a source voltage or power supply voltage VDD through the power tap cell 74. The fourth standard cell C4 may include power tap cells 75 and 76. The power tap cell 75 may be placed to be aligned with the second inline power tap cells 72, and the power tap cell 76 may be placed as an island type between the second and third inline power tap cells 72 and 73. Therefore, a PMOS transistor included in the fourth standard cell C4 may receive the source voltage or power supply voltage VDD through the power tap cell 75, and an NMOS transistor included in the fourth standard cell C4 may receive the ground voltage VSS through the power tap cells 75 and 76.

For example, in a high-performance block or a block where power is much consumed, standard cells including power tap cells of an island type may be placed like the third and fourth standard cells C3 and C4, and thus, an interval between power tap cells may be reduced in the integrated circuit 70. Therefore, power may be smoothly supplied to transistors included in standard cells. Accordingly, performance may be enhanced without an increase in area of the integrated circuit 70, and a power performance area (PPA) gain may be enhanced.

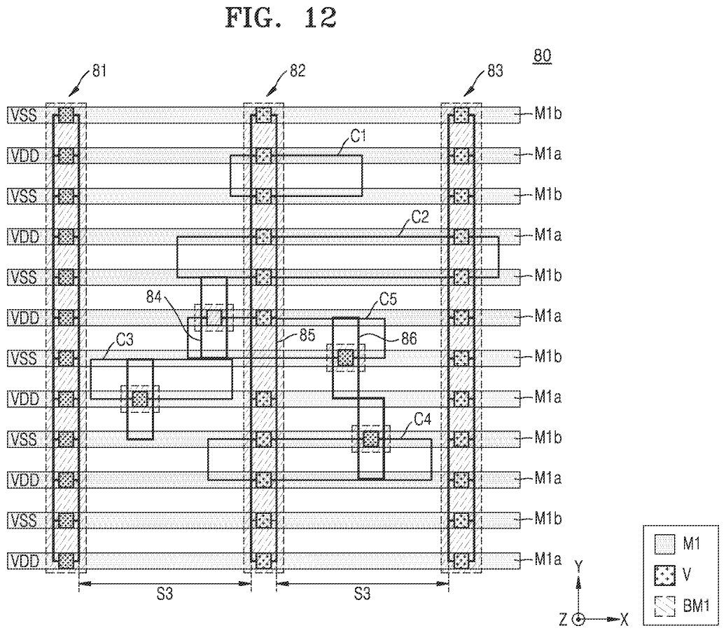

FIG. 12 illustrates a layout of an integrated circuit 80 according to an embodiment.

Referring to FIG. 12, the integrated circuit 80 may correspond to a block or a circuit block where a plurality of standard cells are disposed, so as to perform a specific function. The integrated circuit 80 may include a front wiring layer M1, a backside wiring layer BM1, vias V, and first to third inline power tap cells 81 to 83. According to an embodiment, the integrated circuit 80 may further include first to fifth standard cells C1 to C5, and the first to fifth standard cells C1 to C5 may be freely disposed in the block of the integrated circuit 80.

The integrated circuit 80 may correspond to a modification example of the integrated circuit 60 of FIG. 10 and the integrated circuit 70 of FIG. 11, and descriptions given above with reference to FIGS. 10 and 11 may be applied to an embodiment. The first and second standard cells C1 and C2 may respectively correspond to the first and second standard cells C1 and C2 of FIG. 10, and the third and fourth standard cells C3 and C4 may respectively correspond to the third and fourth standard cells C3 and C4 of FIG. 11. The fifth standard cell C5 may include power tap cells 84 to 86. The power tap cell 84 may be placed as an island type between the first and second inline power tap cells 81 and 82, and thus, a PMOS transistor included in the fifth standard cell C5 may receive a source voltage or power supply voltage VDD through the power tap cell 84. The power tap cell 85 may be placed to be aligned with the second inline power tap cells 82, and thus, the PMOS transistor included in the fifth standard cell C5 may receive the source voltage or power supply voltage VDD through the power tap cell 85. The power tap cell 86 may be placed as an island type between the second and third inline power tap cells 82 and 83, and thus, an NMOS transistor included in the fifth standard cell C5 may receive a ground voltage VSS through the power tap cell 86.

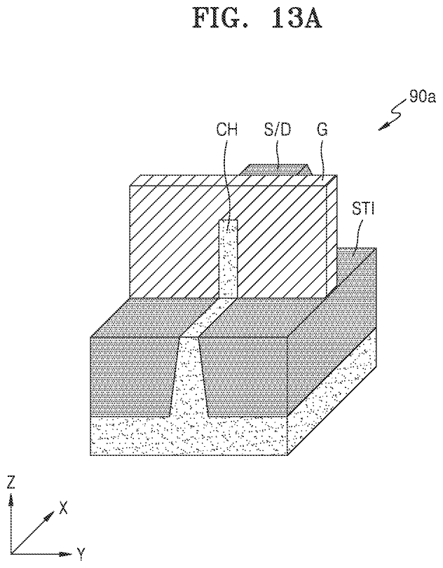

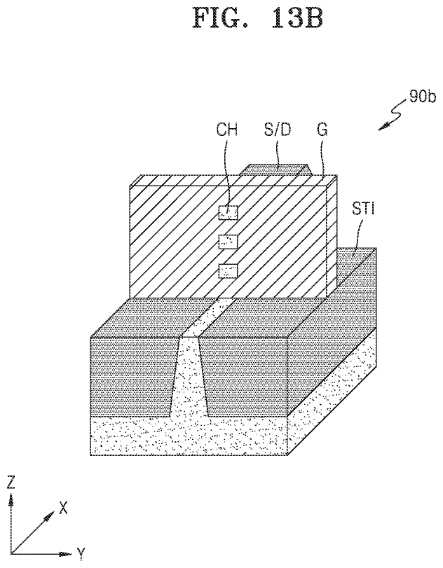

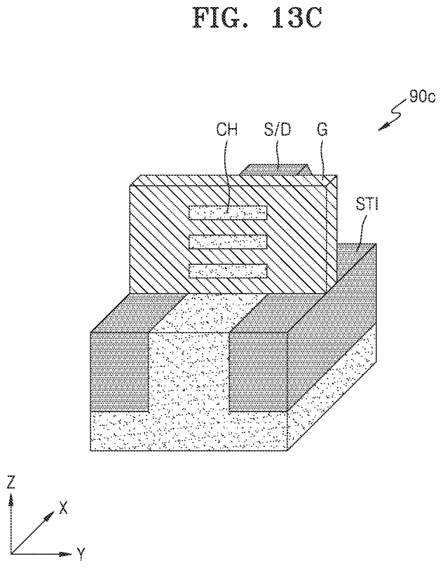

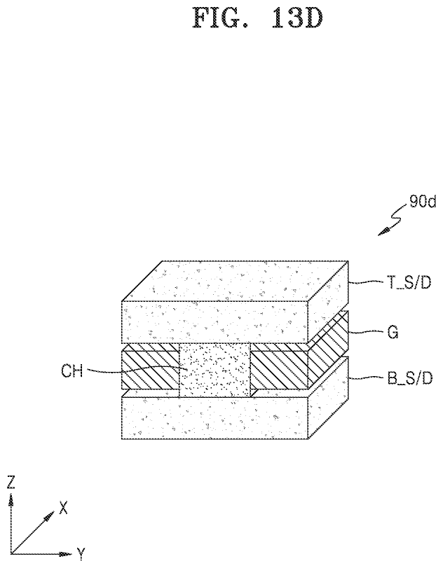

FIGS. 13A to 13D respectively illustrate devices according to some embodiments. For example, FIG. 13A illustrates a Fin field effect transistor (FinFET) 90a, FIG. 13B illustrates a gate-all-around field effect transistor (GAAFET) 90b, FIG. 13C illustrates a multi-bridge channel field effect transistor (MBCFET) 90c, and FIG. 13D illustrates a vertical field effect transistor (VFET) 90d. For the illustration, FIGS. 13A to 13C illustrate an example where one of two source/drain regions has been removed, and FIG. 13D illustrates a cross-sectional surface of the VFET 90d taken along a plane which is parallel to a plane consisting of a second direction Y and a vertical direction Z and passes through a channel CH of the VFET 90d.

Referring to FIG. 13A, the FinFET 90a may be configured by a fin-type active pattern extending in a first direction X and a gate G extending in the second direction Y, between shallow trench isolations (STIs). A source/drain S/D may be formed at each of both sides of the gate G, and thus, a source and a drain may be apart from each other in the first direction X. An insulation layer may be formed between the channel CH and the gate G. In some embodiments, the FinFET 90a may be configured by the gate G and a plurality of active patterns which are apart from one another in the second direction Y.

Referring to FIG. 13B, the GAAFET 90b may be configured by active patterns (i.e., nanowires) which are apart from one another in a vertical direction Z and extend in a first direction X and a gate G which extends in a second direction Y. A source/drain S/D may be formed at each of both sides of the gate G, and thus, a source and a drain may be apart from each other in the first direction X. An insulation layer may be formed between the channel CH and the gate G. The number of nanowires included in the GAAFET 90b is not limited to the illustration of FIG. 13B.

Referring to FIG. 13C, the MBCFET 90c may be configured by active patterns (i.e., nanosheets) which are apart from one another in a vertical direction Z and extend in a first direction X and a gate G which extends in a second direction Y. A source/drain S/D may be formed at each of both sides of the gate G, and thus, a source and a drain may be apart from each other in the first direction X. An insulation layer may be formed between the channel CH and the gate G. The number of nanosheets included in the MBCFET 90c is not limited to the illustration of FIG. 13C.

Referring to FIG. 13D, the VFET 90d may include a top source/drain T_S/D and a bottom source/drain B_S/D, which are apart from each other in a vertical direction Z with a channel CH therebetween. The VFET 90d may include a gate G which surrounds a perimeter of the channel CH, between the top source/drain T_S/D and the bottom source/drain B_S/D. An insulation layer may be formed between the channel CH and the gate G.

However, the transistors according to embodiments are not limited to the structures described above. For example, an integrated circuit may include a ForkFET having a structure where an N-type transistor is relatively closer to a P-type transistor because nanosheets for a P-type transistor and nanosheets for an N-type transistor are separated from one another by a dielectric wall. Also, the integrated circuit may include a bipolar junction transistor as well as a FET such as a CFET, an NCFET, or a CNT FET.

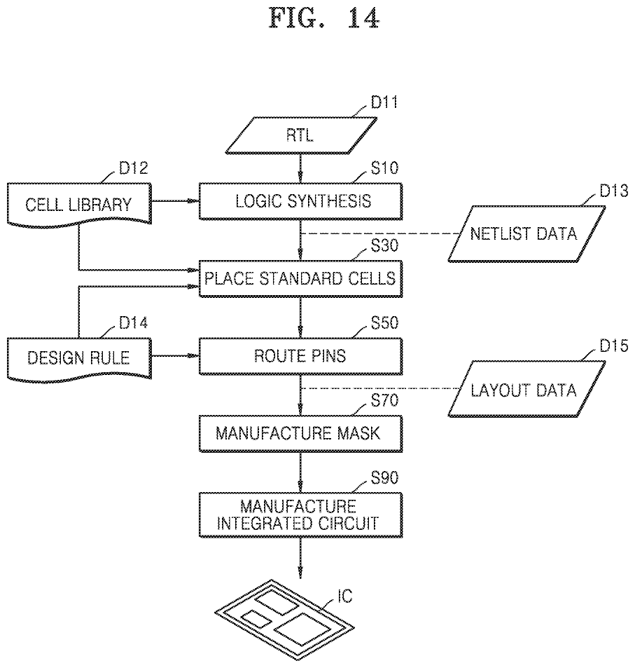

FIG. 14 is a flowchart illustrating a method of manufacturing an integrated circuit, according to an embodiment.

Referring to FIG. 14, the method according to an embodiment may be a method of manufacturing an integrated circuit IC including standard cells and may include a plurality of operations S10, S30, S50, S70, and S90. A standard cell may be a unit of a layout included in an integrated circuit and may be designed to perform a predefined function. A cell library (or a standard cell library) D12 may include information about standard cells, and for example, may include information about a function, a characteristic, a layout, etc. In some embodiments, the cell library D12 may define a tap cell and a dummy cell as well as function cells which generate an output signal from an input signal. In some embodiments, the cell library D12 may define memory cells and dummy cells, which have the same footprint. A design rule D14 may include factors which a layout of the integrated circuit IC has to observe. For example, the design rule D14 may include factors such as a space between patterns, the minimum width of each pattern, and a routing direction of a wiring layer, in the same layer. In some embodiments, the design rule D14 may define the minimum separation distance in the same track of a wiring layer.

In operation S10, a logic synthesis operation of generating netlist data D13 from register transfer level (RTL) data D11 may be performed. For example, a semiconductor design tool (for example, a logic synthesis tool) may perform logic synthesis with reference to the cell library D12 from the RTL data D11 written in hardware description language (HDL) such as very high speed integrated circuit (VHSIC) HDL (VHDL) and Verilog and may generate the netlist data D13 including a netlist or a bitstream. The netlist data D13 may correspond to an input of placement and routing described below.

In operation S30, standard cells may be placed. For example, the semiconductor design tool (for example, a P&R tool) may place standard cells used in the netlist data D13 with reference to the cell library D12. In some embodiments, the semiconductor design tool may place a standard cell in a row extending in an X-axis direction or a Y-axis direction, and the placed standard cell may be supplied with power from a power rail extending along boundaries of the row.

In operation S50, pins of standard cells may be routed. For example, the semiconductor design tool may generate interconnections which electrically connect output pins and input pins of the placed standard cells with one another and may generate layout data D15 which defines the placed standard cells and the generated interconnections. The interconnection may include a via of a via layer and/or patterns of wiring layers. The wiring layers may include a front wiring layer which is disposed on a front surface of a substrate and a backside wiring layer which is disposed on a rear surface of the substrate. The layout data D15 may have, for example, a format such as GDSII and may include geometric information about the standard cells and the interconnections. The semiconductor design tool may refer to the design rule D14 while the pins of the standard cells are being routed. The layout data D15 may correspond to an output of placement and routing. Operation S50 or operations S30 and S50 may be referred to as a method of designing an integrated circuit.

In an embodiment, a standard cell may include a power tap cell and the power tap cell may include at least one via. The at least one via may electrically connect a backside wiring layer with a front wiring layer. In an operation of placing standard cells, a specific inline power tap cell of a row of inline power tap cells may be swapped with a standard cell including a power tap cell, and thus, the degree of freedom in placement of standard cells may be enhanced.

In an embodiment, a standard cell may include power tap cells which are apart from one another in a first direction, and each of the power tap cells may include at least one via. When a width of a standard cell in the first direction is greater than an interval between inline power tap cells, power tap cells included in standard cells may be placed to be aligned with the inline power tap cells. Accordingly, standard cells having a large size may be freely placed.

In an embodiment, a standard cell including a power tap cell may be disposed between inline power tap cells, and in this case, the power tap cell included in the standard cell may be implemented as an island type. In an embodiment, the standard cell may include first and second power tap cells, the first power tap cell may be implemented as an island type, and the second power tap cell may be implemented as an inline type. Therefore, the first power tap cell may be disposed between inline power tap cells apart from one another, and the second power tap cell may be disposed to be aligned with the row of inline power tap cells.

In operation S70, a process of manufacturing a mask may be performed. For example, optical proximity correction (OPC) for correcting distortion such as refraction caused by a characteristic of light in photolithography may be applied to the layout data D15. Based on data to which OPC is applied, patterns of a mask may be defined for forming patterns disposed in a plurality of layers, and at least one mask (or photomask) for forming the patterns of each of the plurality of layers may be manufactured. In some embodiments, the layout of the integrated circuit IC may be restrictively modified in operation S70, and a process of restrictively modifying the integrated circuit IC in operation S70 may be a post-process for optimizing a structure of the integrated circuit IC and may be referred to as design polishing.

In operation S90, a process of manufacturing the integrated circuit IC may be performed. For example, a plurality of layers may be patterned by using the at least one mask which is manufactured in operation S70, and thus, the integrated circuit IC may be manufactured. Front-end-of-line (FEOL) may include, for example, an operation of planarizing and cleaning a wafer, an operation of forming a trench, an operation of forming a well, an operation of forming a gate line, and an operation of forming a source and a drain. Individual elements (for example, a transistor, a capacitor, and a resistor) may be formed on a substrate by the FEOL. Also, back-end-of-line (BEOL) may include, for example, an operation of performing silicidation of a gate region, a source region, and a drain region, an operation of adding a dielectric, a planarization operation, an operation of forming a hole, an operation of adding a metal layer, an operation of forming a via, and an operation of forming a passivation layer. The individual elements (for example, the transistor, the capacitor, and the resistor) may be connected with one another by the BEOL. In some embodiments, middle-of-line (MOL) may be performed between the FEOL and the BEOL, and contacts may be formed on the individual elements. Subsequently, the integrated circuit IC may be packaged in a semiconductor package and may be used as a part of each of various applications.

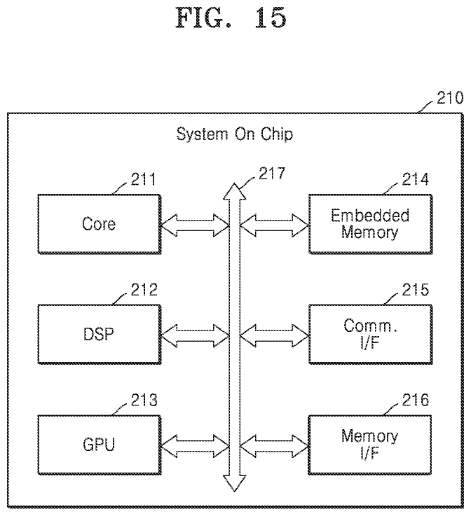

FIG. 15 is a block diagram illustrating a system on chip (SoC) 210 according to an embodiment.

Referring to FIG. 15, the SoC 210 may be referred to as an integrated circuit into which parts of a computing system or other electronic system are integrated. For example, in the SoC 210, an application processor (AP) may include a processor and parts for other functions. The SoC 210 may include a core 211, a digital signal processor (DSP) 212, a graphics processing unit (GPU) 213, an embedded memory 214, a communication interface 215, and a memory interface 216. The elements of the SoC 210 may communicate with one another through a bus 217.

The core 211 may process instructions and may control operations of the elements included in the SoC 210. For example, the core 211 may process a series of instructions, and thus, may drive an operating system and may execute applications of the operating system. The DSP 212 may process a digital signal (for example, a digital signal provided through the communication interface 215), and thus, may generate useful data. The GPU 213 may generate data, which is for an image displayed through a display device, from image data provided from the embedded memory 214 or the memory interface 216 and may encode the image data. In some embodiments, an integrated circuit described above with reference to the drawings may be included in the core 211, the DSP 212, the GPU 213, and/or the embedded memory 214.

The embedded memory 214 may store data needed for operations of the core 211, the DSP 212, and the GPU 213. The communication interface 215 may provide an interface for one-to-one communication or a communication network. The memory interface 216 may provide an interface for an external memory of the SoC 210 (for example, dynamic random access memory (DRAM), flash memory, etc.).

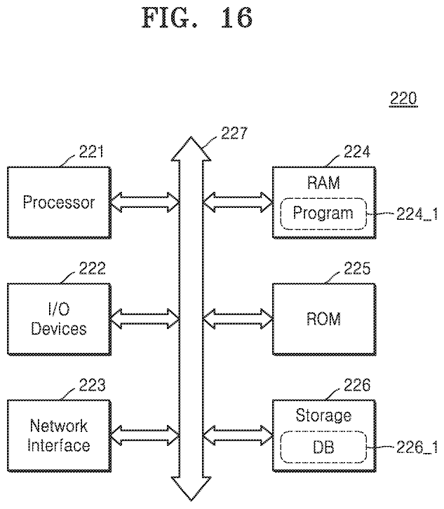

FIG. 16 is a block diagram illustrating a computing system 220 including a memory storing a program, according to an embodiment.

Referring to FIG. 16, the computing system (or a computer) 220 may perform a method of designing an integrated circuit according to embodiments, and for example, may perform at least some of the operations of the flowchart described above. The computing system 220 may be a stationary computing system such as a desktop computer, a workstation, or a server, or may be a portable computing system such as a laptop computer. The computing system 220 may include a processor 221, input/output (I/O) devices 222, a network interface 223, random access memory (RAM) 224, read only memory (ROM) 225, and a storage device 226. The processor 221, the I/O devices 222, the network interface 223, the RAM 224, the ROM 225, and the storage device 226 may be connected with a bus 227 and may communicate with one another through the bus 227.

The processor 221 may be referred to as a processing unit, and for example, may include at least one core for executing an arbitrary instruction set (for example, Intel Architecture-32 (IA-32), 64 bit extension, IA-32, x86-64, PowerPC, Sparc, MIPS, ARM, IA-64, etc.) like a microprocessor, an AP, a DSP, and a GPU. For example, the processor 221 may access a memory (for example, the RAM 224 or the ROM 225) through the bus 227 and may execute instructions stored in the RAM 224 or the ROM 225.

The RAM 224 may store a program 224_1 for a method of designing an integrated circuit according to an embodiment or at least a portion of the program 224_1, and the program 224_1 may allow the processor 221 to perform a method of designing an integrated circuit (for example, at least some of operations included in the methods of FIG. 14). That is, the program 224_1 may include a plurality of instructions executable by the processor 221, and the plurality of instructions included in the program 224_1 may allow the processor 221 to perform, for example, at least some of the operations included in the flowchart described above.

The storage device 226 may maintain data stored therein even when power supplied to the computing system 220 is cut off. The storage device 226 may store the program 224_1 according to an embodiment, and moreover, before the program 224_1 is executed by the processor 221, the program 224_1 or at least a portion thereof may be loaded from the storage device 226 into the RAM 224. Alternatively, the storage device 226 may store a file written in a program language, and the program 224_1 or at least a portion thereof, generated from the file by a compiler, may be loaded into the RAM 224. Also, the storage device 226 may store a database (DB) 226_1, and the database 226_1 may include information needed for designing an integrated circuit (for example, information about designed blocks and/or the cell library D12 and/or the design rule D14 of FIG. 14).

The storage device 226 may store data which is to be processed by the processor 221 or data obtained through processing by the processor 221. That is, the processor 221 may process data stored in the storage device 226 to generate data, based on the program 224_1, and may store the generated data in the storage device 226. For example, the storage device 226 may store the RTL data D11, the netlist data D13, and/or the layout data D15 of FIG. 14.

The I/O devices 222 may include input devices such as a keyboard or a pointing device and may include output devices such as a display device or a printer. For example, a user may trigger execution of the program 224_1 by using the processor 221 through the I/O devices 222, may input the RTL data D11 and/or the netlist data D13 of FIG. 14, and may check the layout data D15 of FIG. 14. The network interface 223 may provide an access to a network outside the computing system 220. For example, the network may include a plurality of computing systems and communication links, and the communication links may include wired links, optical links, wireless links, or other arbitrary types of links.

Hereinabove, example embodiments have been described in the drawings and the specification. Embodiments have been described by using the terms described herein, but this has been merely used for describing the inventive concept and has not been used for limiting a meaning or limiting the scope of the inventive concept defined in the following claims. Therefore, it may be understood by those of ordinary skill in the art that various modifications and other equivalent embodiments may be implemented from the inventive concept. Accordingly, the spirit and scope of the inventive concept may be defined based on the spirit and scope of the disclosure.

While the inventive concept has been particularly shown and described with reference to embodiments thereof, it will be understood that various changes in form and details may be made therein without departing from the spirit and scope of the disclosure.

1. An integrated circuit comprising:
a plurality of standard cells on a front surface of a substrate;
a front wiring layer extending in a first direction on the front surface of the substrate; and
a backside wiring layer on a rear surface of the substrate,
wherein a first standard cell of the plurality of standard cells comprises:
a first gate line and a second gate line arranged apart from each other in the first direction to each extend in a second direction perpendicular to the first direction; and
a plurality of power tap cells between the first gate line and the second gate line,
the plurality of power tap cells comprise a first power tap cell and a second power tap cell apart from the first power tap cell by a first interval in the first direction, and
each of the first power tap cell and the second power tap cell is configured to electrically connect the backside wiring layer with the front wiring layer.

2. The integrated circuit of claim 1, wherein the front wiring layer comprises a first power rail and a second power rail apart from each other in the second direction,
the backside wiring layer comprises a first backside wiring pattern and a second backside wiring pattern,
the first power tap cell comprises a first via extending in a vertical direction between the first power rail and the first backside wiring pattern, and
the second power tap cell comprises a second via extending in the vertical direction between the second power rail and the second backside wiring pattern.

3. The integrated circuit of claim 1, wherein the front wiring layer comprises a first power rail and a second power rail apart from each other in the second direction,
the backside wiring layer comprises a first backside wiring pattern and a second backside wiring pattern,
the first power tap cell comprises a first via extending in a vertical direction between the first power rail and the first backside wiring pattern, and
the second power tap cell comprises a second via extending in the vertical direction between the first power rail and the first backside wiring pattern.

4. The integrated circuit of claim 1, wherein the front wiring layer comprises a first power rail and a second power rail apart from each other in the second direction,
the backside wiring layer comprises a first backside wiring pattern and a second backside wiring pattern,
the first power tap cell comprises:
a first via extending in a vertical direction between the first power rail and the first backside wiring pattern; and
a second via extending in the vertical direction between the second power rail and the second backside wiring pattern, and
the second power tap cell comprises:
a third via extending in the vertical direction between the first power rail and the first backside wiring pattern; and
a fourth via extending in the vertical direction between the second power rail and the second backside wiring pattern.

5. The integrated circuit of claim 1, wherein the plurality of power tap cells further comprise a third power tap cell apart from the second power tap cell by the first interval in the first direction.

6. The integrated circuit of claim 1, wherein the first power tap cell is configured to transfer a positive supply voltage from the backside wiring layer to the front wiring layer.

7. The integrated circuit of claim 1, wherein the first power tap cell is configured to transfer a negative supply voltage from the backside wiring layer to the front wiring layer.

8. The integrated circuit of claim 1, wherein a length of each of the plurality of power tap cells in the second direction is equal to a length of the first standard cell in the second direction.

9. The integrated circuit of claim 1, wherein the first power tap cell is apart from a first cell boundary of the first standard cell in the first direction,
the second power tap cell is apart from a second cell boundary of the first standard cell in the first direction, and
the first cell boundary is opposite to the second cell boundary in the first direction.

10. An integrated circuit comprising:
a plurality of standard cells on a substrate;
a front wiring layer extending in a first direction on a front surface of the substrate; and
a backside wiring layer on a rear surface of the substrate,
wherein a first standard cell of the plurality of standard cells comprises:
a first gate line and a second gate line arranged apart from each other in the first direction to each extend in a second direction perpendicular to the first direction; and
a power tap cell between the first gate line and the second gate line, the power tap cell including at least one via electrically connecting the backside wiring layer with the front wiring layer.

11. The integrated circuit of claim 10, wherein the front wiring layer comprises a first power rail overlapping a first cell boundary of the first standard cell,
the backside wiring layer comprises a first backside wiring pattern,
the at least one via comprises a first via overlapping the first power rail and extending in a vertical direction between the first backside wiring pattern and the first power rail, and
the first cell boundary extends in the first direction.

12. The integrated circuit of claim 11, wherein the front wiring layer further comprises a second power rail overlapping a second cell boundary of the first standard cell,
the backside wiring layer comprises a second backside wiring pattern,
the at least one via further comprises a second via overlapping the second power rail and extending in the vertical direction between the second backside wiring pattern and the second power rail, and
the second cell boundary extends in the first direction and is opposite to the first cell boundary.

13. The integrated circuit of claim 11, wherein the first via is configured to transfer a positive supply voltage from the first backside wiring pattern to the first power rail.

14. The integrated circuit of claim 11, wherein the first via is configured to transfer a negative supply voltage from the first backside wiring pattern to the first power rail.

15. The integrated circuit of claim 10, wherein a length of the power tap cell in the second direction is equal to a length of the first standard cell in the second direction.

16. The integrated circuit of claim 10, wherein the power tap cell is apart from a first cell boundary of the first standard cell in the first direction and is apart from a second cell boundary of the first standard cell in the first direction, and
the first cell boundary is opposite to the second cell boundary in the first direction.

17. An integrated circuit comprising:
a plurality of standard cells on a front surface of a substrate;
a front wiring layer including a plurality of front wiring patterns arranged apart from one another in a second direction perpendicular to a first direction to each extend in the first direction on the front surface of the substrate;
a backside wiring layer on a rear surface of the substrate; and
a plurality of first inline power tap cells arranged in one row in the second direction to electrically connect the backside wiring layer with the front wiring layer,
wherein a first standard cell of the plurality of standard cells comprises:
a first gate line and a second gate line arranged apart from each other in the first direction to each extend in the second direction; and
a first power tap cell between the first gate line and the second gate line to electrically connect the backside wiring layer with the front wiring layer, and
the first power tap cell is aligned with the plurality of first inline power tap cells.

18. The integrated circuit of claim 17, wherein a second standard cell of the plurality of standard cells comprises a second power tap cell configured to electrically connect the backside wiring layer with the front wiring layer, and
the second power tap cell is not aligned with the plurality of first inline power tap cells.

19. The integrated circuit of claim 18, further comprising a plurality of second inline power tap cells arranged in one row in the second direction and disposed apart from the plurality of first inline power tap cells in the first direction to electrically connect the backside wiring layer with the front wiring layer,
wherein the second power tap cell is between the plurality of first inline power tap cells and the plurality of second inline power tap cells.

20. The integrated circuit of claim 19, wherein the second standard cell further comprises a third power tap cell configured to electrically connect the backside wiring layer with the front wiring layer, and
the third power tap cell is aligned with the plurality of first inline power tap cells.

21-23. (canceled)
